(19) United States
(12) Patent Application Publication
(10) Pub. No.: US 2010/0246309 A1
(43) Pub. Date: Sep. 30, 2010

(54) SEMICONDUCTOR MEMORY

(75) Inventors: Yasushi SHIMONO, Ome (JP); Kaoru Yoshida, Musashimurayama (JP); Akira Ohta, Ome (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/684,998

(22) Filed: Jan. 11, 2010

(30) Foreign Application Priority Data
Mar. 24, 2009 (JP) 2009-071135

(51) Int. Cl. G11C 8/08

(52) U.S. Cl. 365/230.06; 365/154

(57) ABSTRACT

An SRAM module includes bit cells arranged within an SRAM array of N×M, and a replica SRAM cell array of a replica bit cell used for bit cell performance measurement, and can control the number of replica bit cells used for performance measurement. When the clock generator circuit generates an internal pulse upon receiving a clock, the clock generator circuit generates a leading edge of a pulse by a clock (clk), and generates a trailing edge thereof by a delay circuit including the delay of the replica bit cells. The internal pulse is used for controlling the activation time of the word lines for selecting the memory cell, and the timing of a bit line control circuit (a bit line precharger circuit, an address logic circuit, and a sense amplifier circuit).

### CLAIM OF PRIORITY

The present application claims priority from Japanese patent application JP 2009-071135 filed on Mar. 24, 2009, the content of which is hereby incorporated by reference into this application.

### FIELD OF THE INVENTION

The present invention relates to an architecture of a semiconductor memory having a large number of bit cells arranged in a matrix.

### BACKGROUND OF THE INVENTION

A semiconductor memory includes memory cells arranged in a matrix. Each row of the memory cells is connected to a word line. When the word line is activated by decoding an address, bit cells of the row connected to the activated word line are accessed. As a result of activating the word line, data in each bit cell on that row passes through a pair of bit lines on a column. A sense amplifier samples a voltage difference on the bit line at an appropriate time, and the sampled data is carried to another arbitrary data bus.

JP-A-Hei08 (1996)-138383 and U.S. Pat. No. 6,212,117 disclose a memory timing control. In JP-A-Hei08 (1996)-138383, with provision of a redundant bit cell column for determining a sampling time of the sense amplifier, a redundant bit cell is activated at the same timing as an activating timing of the word line to generate a timing associated with the voltage difference on the bit line due to normal memory cells. As a result, sampling with a necessary amplitude is enabled to speed up an access time. In U.S. Pat. No. 6,212,117, a delay of a dummy cell output is used for row predecoding.

### SUMMARY OF THE INVENTION

Originally, the activation of the word lines is required until the sampling time of the sense amplifier, and thereafter data is decided by the sense amplifier. Also, a general cycle time of an SRAM is frequently determined by a total of an activation time of the word lines and a precharge time of the bit lines. This architecture suffers from such a problem that the activation time of the word lines cannot be suppressed to a required minimum, and the cycle time cannot be speeded up.

Also, when a timing of a termination time of the activation of the word lines is generated by an inverter chain within a control unit, there arise the following severe drawbacks. First, in order to obtain a high circuit density, a small-sized transistor is frequently used for the bit cell. The transistor is normally smaller than the smallest gate width size of a logic region. The small transistor is liable to be affected by a variation of a manufacturing process due to a typical device within an inverter chain in the logic region, and delay mismatching may occur. Second, the inverter chain delay is controlled by an NMOS and a PMOS, but a memory cell current has only a function of the NMOS. Those drawbacks make it difficult to perform the stable operation and speed-up of the cycle time because delay mismatching may occur due to the manufacturing process variation and a change in voltage and temperature.

A summary of a typical configuration of the present invention will be briefly described below among configurations of the invention described in the present application. That is, there is provided a clock generator circuit using a replica SRAM cell column and a replica bit cell for a RAM operation time. In the replica SRAM cell column, since a given number of bit cells is set in a given state and connected at the same time, the normal bit cells generate a delay time equivalent to a time necessary for sampling. When the replica bit cell is made identical in diffusion layout with the normal bit cells, the stable operation is enabled because a variation in a time required for sampling of the normal bit cells and a variation in a delay time of the replica cell follow a change in the manufacture process and the voltage temperature.

In the clock generator circuit that generates a control signal for bit cell periphery such as a word line activation time and sampling of the sense amplifier, a clock pulse time that determines the operation of the SRAM is generated by using the delay time generated by the replica SRAM cell column.

A word line activation signal, a sampling time of the sense amplifier, a bit line precharge time, and so on are generated by using the clock pulse generated in the clock generator circuit. In this state, the sampling time of the sense amplifier and the termination time of the word line activation signal are adjusted by an address logic circuit and a column I/O logic circuit.

The advantage of the present invention resides in that a clock pulse time for determining the operation time of the SRAM is generated by using a time necessary for a potential difference to appear on the bit lines as a delay time. The word line activation signal, the sampling time of the sense amplifier, the bit precharge time, and so on are generated by using the clock pulse time. As a result, the delay mismatching due to the variation in the manufacturing process and the change in the voltage and temperature can be prevented, and the stable operation and the speed-up of the cycle time can be performed.

### BRIEF DESCRIPTION OF THE DRAWINGS

FIG. 1 is a diagram showing a memory array;

FIG. 2 is a diagram showing a clock generator circuit; and

FIG. 3 is a diagram showing the operation timing of the circuit.

### DETAILED DESCRIPTION OF THE PREFERRED EMBODIMENTS

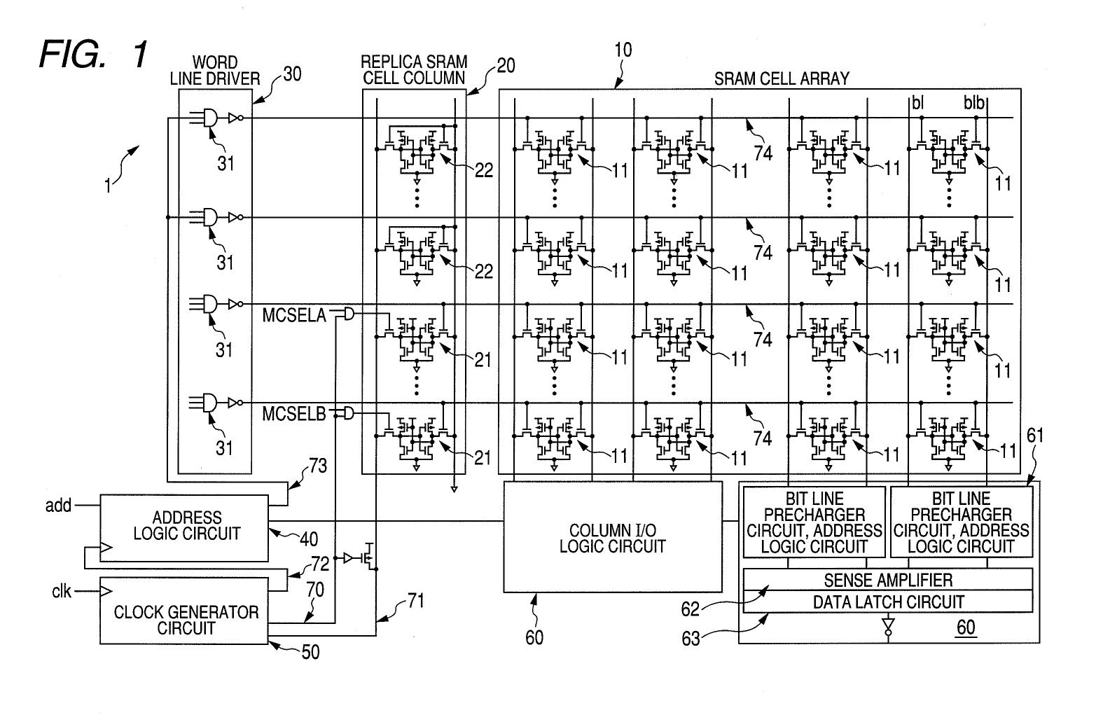

FIG. 1 is a diagram showing a memory array system 1. The memory array system 1 includes a SRAM cell array 10, the word line driver 30, the column IO logic circuit 60, the address logic circuit 40, the clock generator circuit 50, and the replica SRAM cell column 20.

The SRAM cell array 10 is a circuit section that stores information of the logic circuit section as memory cell information. The word line driver 30 is a circuit section for selecting the respective SPAM cells. The column IO logic circuit 60 is a circuit section for controlling selection of bit lines connected to memory cells, and read and write of the memory cell, information. The address logic circuit 40 is a circuit section for controlling selection of the word line driver 30 and the column IO logic circuit 60. Also, the clock generator circuit 50 and the replica SRAM cell column 20 are control sections for generating various signal timings of the word line driver 30 and the column IO logic circuit 60.

The memory array system 1 includes the SRAM cell array 10. The SRAM cell array 10 has a large number of memory bit cells 11 arranged in a matrix of N×M. One of N word lines 74 is connected to pass transistors of the memory cells on one row, and each bit cell is connected to a pair of bit lines (bl/blb). The word lines indentify the respective rows by the address logic circuit 40, a final decoder circuit 31, and addresses (add) for indentifying the respective rows.

Each of the bit line pairs on each column is connected to the column 10 logic circuit 60 each of which is provided to plural bit line pairs. The column 10 logic circuit 60 provides a bit line precharger circuit, an address logic circuit, and an address logic circuit for each bit line pair. The column 10 logic circuit 60 controls read and write times, selects one bit line pair from the plural bit line pairs, and connects the selected bit line pair to a sense amplifier. The address logic circuit 40 and the final decoder circuit 31 electrically select one of the N word lines, and transmits electric storage information within the memory bit cell 11 connected to the selected word line 74 to the respective bit lines connected to that memory bit cell 11 as a voltage level difference. The voltage level difference of the bit line pair is amplified to a level that can be discriminated by the logic circuit by electrically connecting one of the plural bit line pairs to the sense amplifier by an address logic circuit of the column 10 logic circuit 60, and the amplified voltage level difference is outputted as memory cell information via a data latch circuit 63.

The clock generator circuit 50 is provided for concentratedly controlling the respective circuit activation time timings of the word lines 74 in the memory array system 1, the bit line precharger circuit of the column IO logic circuit 60, the address logic circuit, and the sense amplifier. A delay time obtained by activating plural replica bit cells 21 is used for a delay circuit that generate the activation time timing and the sampling timing of the amplifier circuit. Also, plural replica bit cells 21 control the number activated by an external signal (mcsel), and adjust the activation time timing. With use of a delay time of the replica bit cells for the activation time timing and the sampling timing, a timing interlocked with the voltage difference to the bit lines of the memory cells can be generated. Therefore, the delay mismatching of the stable operation, the activation timing, and the sampling timing does not occur, and the timing adjustment is easy, and high speed operation can be realized as much.

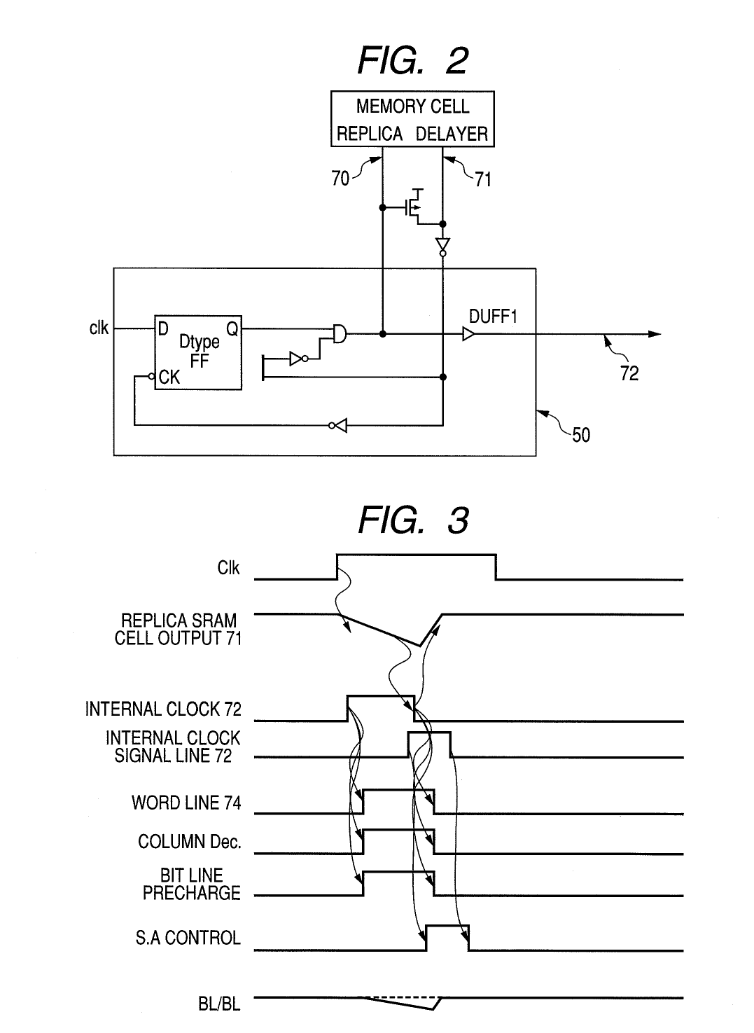

FIG. 2 is a diagram showing the clock generator circuit 50. The clock generator circuit 50 is made up of a D-type FF and a logic circuit. The clock generator circuit 50 receives an external clock signal (clk), electrically connects a leading edge of the clock signal so as to form a leading edge of an internal clock signal 72, and electrically connects a gate of a transfer MOS of the replica SRAM cell column 20. The clock generator circuit 50 feeds an output signal 71 that responds after the delay time corresponding to the number of replica memory cells electrically connected back to the clock generator circuit 50 to generate a tailing edge of the internal clock 72 by using the feedback signal. A timing of electrically connecting to the gate of the transfer MOS of the replica SRAM cell column 20 does not coincide with a timing of selecting the word line 74 for selecting the SRAM cell. Also, a variation in the logic threshold value due to the process variation can be reduced by making a gate channel length of a logic circuit that receives a signal from the replica bit line thicker than the gate channel length of the normal logic circuit.

FIG. 3 is a diagram showing an interlocking relationship of the respective signals of the memory array system.

What is claimed is:

1. A semiconductor memory, comprising:
SRAM cells arranged in a matrix;
replica SRAM cells; and
a word line driver that drives pass transistors of the SRAM cell and the replica SRAM memory cell through word lines,
wherein the word line driver starts to drive the word lines upon receiving an external clock signal, and stops driving the word lines according to an output signal output from the replica memory cell through the pass transistor rendered conductive by driving the word line.

2. The semiconductor memory according to claim 1,
wherein a plurality of output signals from the replica SRAM cells is outputted through a pair of bit lines, and
wherein conduction and non-conduction of the pass transistors of the replica SRAM cells are controlled according to an external signal.

3. A method of controlling a word line in a semiconductor memory including SRAM cells arranged in a matrix, replica SRAM cells, and a word line driver that drives pass transistors of the SRAM cell and the replica SRAM memory cell through word lines, the method comprising:
starting to drive the word lines upon receiving an external clock signal by the word line driver, and
stopping driving the word lines according to an output signal output from the replica memory cell through the pass transistor rendered conductive by driving the word line by the word line driver.

4. The control method according to claim 3, further comprising:
outputting a plurality of output signals from the replica SRAM cells through a pair of bit lines, and
controlling conduction and non-conduction of the pass transistors of the replica SRAM cells according to an external signal.
